(19) United States
(12) Patent Application Publication
(10) Pub. No.: US 2015/0167158 A1
(43) Pub. Date: Jun. 18, 2015

(54) Atomic Layer Deposition of Transition Metal Thin Films Using Boranes as the Reducing Agent

(71) Applicant: Wayne State University, Detroit, MI (US)

(72) Inventors: Charles H. WINTER, Bloomfield Hills, MI (US); Thomas Joseph KNISLEY, Monroe, MI (US)

(21) Appl. No.: 14/630,086

(22) Filed: Feb. 24, 2015

Related U.S. Application Data
(62) Division of application No. 13/493,560, filed on Jun. 11, 2012.

(51) Int. Cl. C23C 16/18; C23C 16/455

(52) U.S. Cl. CPC C23C 16/18; C23C 16/45553

(57) ABSTRACT

A method for forming a metal comprises contacting a compound having formula 1 with a compound having formula 2 with an amine borane:

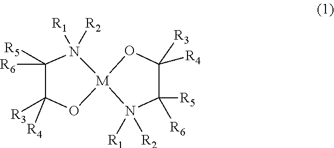

wherein:
M is Cu, Ni, Co, and Mn;
R₁R₂, R₃ are each independently C₁-C₆ alkyl; and
R₄-R₆ are each independently hydrogen or C₁-C₆ alkyl. A method for making a metal film by an atomic layer deposition process using a compound having formula (1) is also provided.

### FIELD OF THE INVENTION

In at least one aspect, the present invention is related to the formation of metal films from “metalorganic” precursors.

### BACKGROUND OF THE INVENTION

The growth of thin films is a central step in the fabrication of many functional materials and devices. While film growth efforts have been traditionally directed toward films greater than 100 nm, recent trends in several areas are calling for the growth of films ranging in thickness from a few atomic layers up to tens of nanometers.

In the microelectronics area, copper has replaced aluminum as the interconnect material in integrated circuits due to its lower resistivity and higher resistance to electromigration. Ultrathin (2-8 nm) manganese-silicon-oxygen layers have been proposed as replacements for existing nitride-based copper diffusion barrier layers in future devices. Since copper does not nucleate well on SiO₂ and other surfaces, it is difficult to deposit copper metal onto the surface features of microelectronic substrates. Accordingly, there has been considerable interest in the formation of seed layers of metals such as chromium, cobalt, and others which adhere better to substrates, and upon which copper films can be subsequently grown.

Nickel and nickel silicide (NiSi) are important contact materials in device fabrication. Magnetoresistive random access memory devices require the growth of thin, conformal layers of magnetic metals such as nickel, cobalt, or iron. Microelectronics device dimensions are scheduled to reach 22 nm by 2012, and existing deposition processes will soon not be able to provide the required level of thickness control and conformality, especially in high aspect ratio features.

Atomic layer deposition (“ALD”) is a thin film deposition technique that addresses many of the current technological demands. ALD affords inherently conformal coverage and sub-nanometer film thickness control due to its self-limited growth mechanism. In a typical ALD process, a substrate is contacted with a first chemical composition that modifies the substrate for a first predetermined period of time (a pulse). Such modification involves adsorption to the surface of the substrate, reaction with the surface of the substrate, or a combination of adsorption and reaction. A purging gas is introduced to remove any lingering first gaseous chemical composition in the vicinity of the substrate. A second gaseous chemical composition that reacts with the modified substrate surface is introduced for a second predetermined period of time into the vicinity of the substrate to form a portion of the thin film. A purging gas is subsequently introduced to remove any lingering second chemical composition in the vicinity of the substrate. These steps of contacting the substrate with the first chemical composition, purging, contacting the substrate with the second gaseous chemical composition, and purging are usually repeated a plurality of times until a film of desired thickness is coated onto the substrate. Although the prior art ALD processes work well, there is unfortunately only a limited number of chemical precursors having the requisite thermal stability, reactivity, and vapor pressure for ALD.

Accordingly, there is a need for thermally stable volatile precursors suitable for depositing thin films by atomic layer deposition.

### SUMMARY OF THE INVENTION

The present invention solves one or more problems of the prior art by providing a method for forming a metal. The method comprises contacting a compound having formula 1 with a compound having formula 2 with a borane:

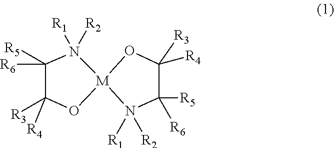

wherein:

M is Cu, Ni, Co, and Mn;

R₁R₂, R₃ are each independently C₁-C₆ alkyl; and

R₄-R₆ are each independently hydrogen or C₁-C₆ alkyl.

In another embodiment, a method of forming a metal film by an atomic layer deposition process is provided. The method comprises a deposition which includes contacting the substrate with vapor of a compound having formula 1 set forth above such that at least a portion of the vapor of the compound having formula 1 adsorbs or reacts with a substrate surface to form a modified surface. The deposition cycle further includes contacting the modified surface with a vapor of a borane to react and form at least a portion of the metal film.

### BRIEF DESCRIPTION OF THE DRAWINGS

Exemplary embodiments of the present invention will become more fully understood from the detailed description and the accompanying drawings, wherein:

FIG. 1 is a schematic illustration of an ALD deposition system used in an embodiment of the present invention;

FIG. 2 provides an x-ray crystal structure of bis(dimethylamino-2-propoxy)nickel(II) with thermal ellipsoids at 50% probability level;

FIG. 3 provides thermogravimetric analysis (TGA) performed to understand the thermal stability and volatility of bis(dimethylamino-2-propoxy)nickel(II);

FIG. 4 provides a cross-sectional scanning electron micrograph (SEM) of a Cu film deposited on SiO₂ at 150° C. using borane N,N-diisopropylethylamine at purge lengths of 5 seconds;

FIG. 5 provides a cross-sectional SEM micrograph of a Cu film deposited on Ru/SiO₂ at 150° C. using borane N,N-diisopropylethylamine at purge lengths of 10 seconds;

FIG. 6 provides an x-ray photoelectron spectroscopy (XPS) spectrum of a Cu film deposited on SiO₂ at 150° C. using borane N,N-diisopropylethylamine at purge lengths of 5 seconds; and

FIG. 7 provides a surface SEM micrograph of a Cu film deposited on Ru/SiO₂ at 150° C. using borane N,N-diisopropylethylamine at purge lengths of 10 seconds.

### DESCRIPTION OF THE INVENTION

Reference will now be made in detail to presently preferred compositions, embodiments and methods of the present invention which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

Throughout this application, where publications are referenced, the disclosures of these publications in their entireties are hereby incorporated by reference into this application to more fully describe the state of the art to which this invention pertains.

In an embodiment, a method for depositing a metal film on a surface of a substrate using a precursor compound having formula 1 is provided:

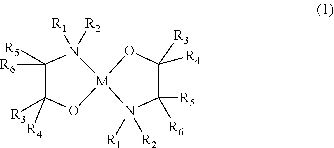

wherein M is Cu, Ni, Co, and Mn; R₁, R₂, R₃ are each independently C₁-C₆ alkyl; and R₄-R₆ are each independently hydrogen or C₁-C₆ alkyl. In a refinement, R₁, R₂, R₃ are each independently methyl and R₄-R₆ are each independently hydrogen. In another refinement, R₁, R₂, R₃ are each independently selected from the group consisting of methyl, isopropyl, n-propyl, n-butyl, sec-butyl, and iso-butyl. The method includes a step of contacting the compound having formula 1 with a borane. In a refinement, the borane is an amine borane. Typically, the compound having formula 1 is contacted with the borane at a temperature from about 50 to 400° C. The present reaction is used in an ALD process as set forth below.

In a variation of the present embodiment, the amine borane has formula (2):

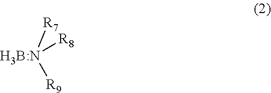

and
R₇-R₉ are each independently hydrogen or C₁-C₆ alkyl. In a refinement, R₇, R₈, and R₉ are each independently selected from the group consisting of methyl, isopropyl, n-propyl, n-butyl, sec-butyl, and iso-butyl. Specific examples of compounds within the scope of formula 2 include H₃B:NH(CH₃)₂, H₃B:NH(C₂H₅)₂, H₃B:N(C₂H₅)(iso-C₃H₇)₂, and the like. In a further refinement, R₇ and R₈, are joined to form a 5 or 6 membered ring. An example of this later refinement is provided by the amine borane having formula (3):

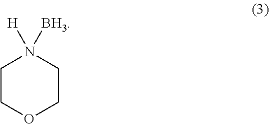

In another variation, the amine borane having formula (4):

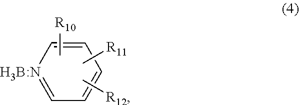

wherein R₁₀-R₁₂ are each independently C₁-C₆ alkyl. Specific examples of compounds having formula (4) include:

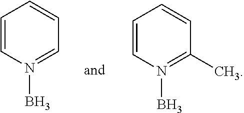

In another variation, the borane has the following formula selected from the group consisting of B₁₀H₁₄,

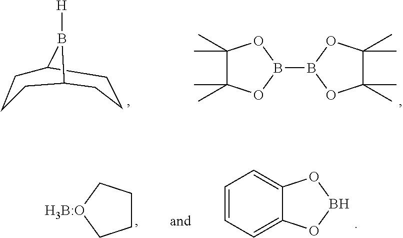

In another embodiment, an ALD process for forming a metal film on a substrate is provided. The method includes a deposition cycle including contacting the substrate with vapor of a compound having formula 1:

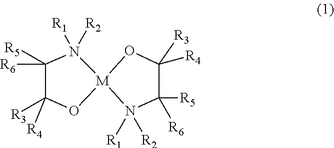

such that at least a portion of the vapor of the compound having formula 1 adsorbs or reacts with a substrate surface to form a modified surface. The deposition cycle further includes contacting the modified surface with a vapor of an amine borane to react and form at least a portion of the metal film. The details for M, R₁-R₆, and the amine borane are the same as those set forth above including all refinements and variations.

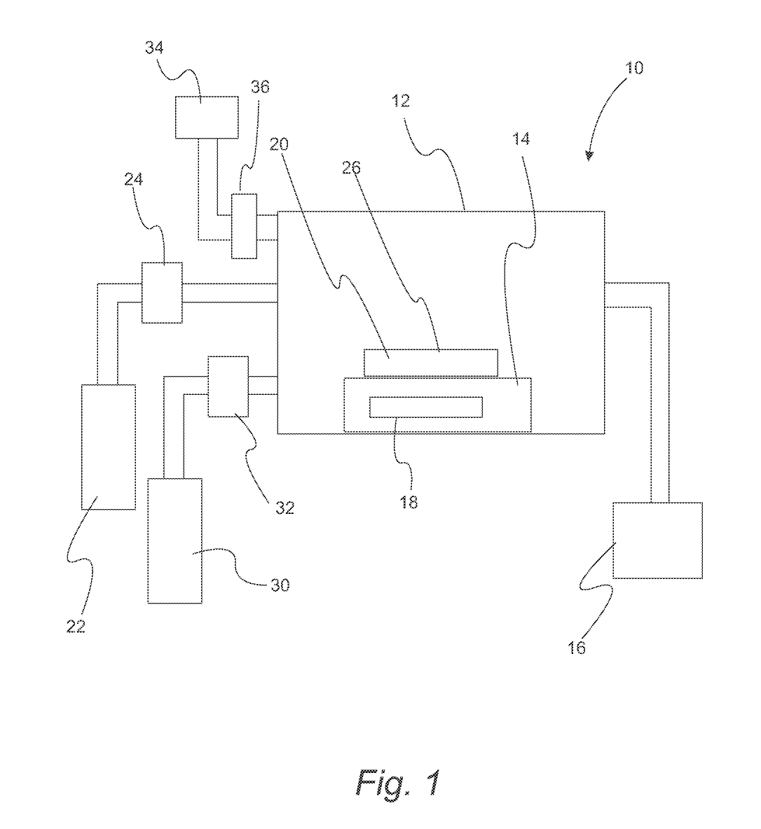

With reference to FIG. 1, deposition system 10 includes reaction chamber 12, substrate holder 14, and vacuum pump 16. Typically, the substrate is heated via heater 18. The method has a deposition cycle comprising contacting substrate 20 with a vapor of a metal-containing compound described by formula 1 as set forth above. In particular, the vapor is introduced from precursor source 22 into reaction chamber 12 for a predetermined pulse time. The pulse time is controlled via control valve 24. At least a portion of the vapor of the metal-containing compound modifies (e.g, adsorbs or reacts with) substrate surface 26 to form a modified surface. The method further comprises contacting the modified surface with a vapor of a borane as set forth above from borane source 30 for a predetermined pulse time. The pulse time is controlled via control valve 32. The borane causes the metal-containing compound to react and form at least a portion of the thin metal film on the surface of the substrate. The reduced pressure of chamber 12 is maintained by vacuum pump 16.

In a variation of the present embodiment, the method further comprises removing at least a portion of the vapor of the metal containing compound having formula 1 that is lingering in the gas phase (i.e., has not adsorbed or reacted with the substrate) from the vicinity of the substrate before introducing the vapor of the activating compound and removing at least a portion of the vapor of the activating compound from the vicinity of the substrate. The metal-containing compound and borane are removed in purging steps by introducing a purge gas from purge source 34 into reaction chamber 12 for a predetermined purge time. The purge time is controlled by control valve 36.

In another variation, the method further includes at least one additional deposition cycle comprising sequentially contacting the substrate with the vapor of a metal-containing compound having formula 1 and then the vapor of an amine borane. In some refinements, the substrate is contacted for a plurality of additional deposition cycles. For example, the substrate may be contacted with from 1 to several thousand deposition cycles depending on the thickness of the film desired.

During film formation by the method of the present embodiment, the substrate temperature will be at a temperature suitable to the properties of the chemical precursor(s) and film to be formed. In a refinement of the method, the substrate is set to a temperature from about 0 to 1000° C. In another refinement of the method, the substrate has a temperature from about 50 to 450° C. In another refinement of the method, the substrate has a temperature from about 100 to 250° C. In still another refinement of the method, the substrate has a temperature from about 150 to 400° C. In another refinement of the method, the substrate has a temperature from about 200 to 300° C.

Similarly, the pressure during film formation is set at a value suitable to the properties of the chemical precursors and film to be formed. In one refinement, the pressure is from about 10⁻⁶ Torr to about 760 Torr. In another refinement, the pressure is from about 0.1 millitorr to about 10 Torr. In still another refinement, the pressure is from about 1 to about 100 millitorr. In yet another refinement, the pressure is from about 1 to 20 millitorr.

Pulse times and purge times also depend on the properties of the chemical precursors and the geometric shape of the substrates. Thin film growth on flat substrates uses short pulse and purge times, but pulse and purge times in ALD growth on 3-dimensional substrates can be very long. Therefore, in one refinement, pulse times and purge times are each independently from about 0.0001 to 200 seconds. In another refinement, pulse and purge times are each independently from about 0.1 to about 10 seconds.

The following examples illustrate the various embodiments of the present invention. Those skilled in the art will recognize many variations that are within the spirit of the present invention and scope of the claims.

Preparation of Bis(dimethylamino-2-propoxy)copper(II) (1).

A 100 mL Schlenk flask, equipped with a magnetic stir bar and rubber septum, is charged with 1-dimethylamino-2-propanol (1.000 g, 9.69 mmol) and tetrahydrofuran (20 mL). To this stirred solution at ambient temperature is slowly added potassium hydride (0.427 g, 10.66 mmol) and the resultant colorless solution is stirred for 6 hours. This is then slowly added to a stirred suspension of CuCl₂ (0.651 g, 4.84 mmol) in tetrahydrofuran (30 mL). The resultant purple solution is refluxed for 18 hours. The volatile components are then removed under reduced pressure and the resultant green solid is dissolved in toluene (30 mL). The solution is filtered through a 1-cm pad of Celite on a coarse glass frit, and the toluene is then removed under reduced pressure. An analytically pure sample of the product is obtained by sublimation at 60° C./0.05 Torr as black-dark purple crystals (0.545 g, 42%): mp 139-141° C. (dec: 185-188° C.)

Preparation of Bis(dimethylamino-2-propoxy)nickel(II) (2).

A 100 mL Schlenk flask, equipped with a magnetic stir bar and rubber septum, is charged with 1-dimethylamino-2-propanol (1.000 g, 9.69 mmol) and tetrahydrofuran (20 mL). To this stirred solution at ambient temperature is slowly added potassium hydride (0.040 g, 10.00 mmol) and the resultant colorless solution is stirred for 3 hours. This is then slowly added to a stirred suspension of NiCl₂.CH₃CN (0.826 g, 2.715 mmol) in tetrahydrofuran (30 mL). The resultant dark green solution is stirred for 17 hours at ambient temperature. The volatile components are then removed under reduced pressure and the resultant dark green solid is dissolved in hexane (35 mL). The solution is filtered through a 1-cm pad of Celite on a coarse glass frit, and the hexane is then removed under reduced pressure. An analytically pure sample of complex 2 is obtained by sublimation at 80° C./0.05 Torr as dark green crystals (0.987 g, 77%): mp 143-145° C. (dec: 161-172° C.); IR (Nujol, cm⁻¹) 1353 (m), 1259 (m), 1135 (m), 1088 (s), 1020 (m), 945 (s), 862 (m), 836 (m); ¹H NMR (C₆D₆, 23° C., δ) 0.98 (d, CH₃COCH₂, 3H), 1.31,1.82 (m,CH₂, 2H), 1.92 (t, N(CH₃), 3H), 2.49 (d, N(CH₃), 3H), 3.57 (m, CHO, 1H); ¹³C {¹H} NMR (C₆D₆, 23° C., ppm) 22.18 (CH₃CO), 67.86 (OCCH₃H), 75.31 (CH₂), 46.02 and 49.51 N(CH₃)₂. Preparative sublimation was carried out with 0.7 g of crystals at 85° C./0.05 Torr for 4 h: percent recovery: 95%, percent nonvolatile residue: 0.7%.

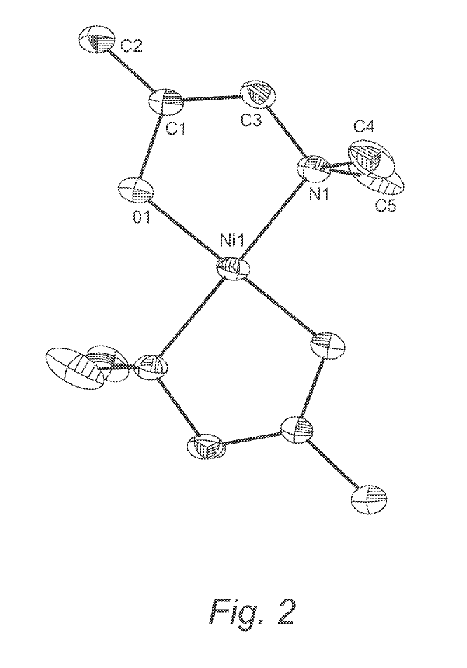

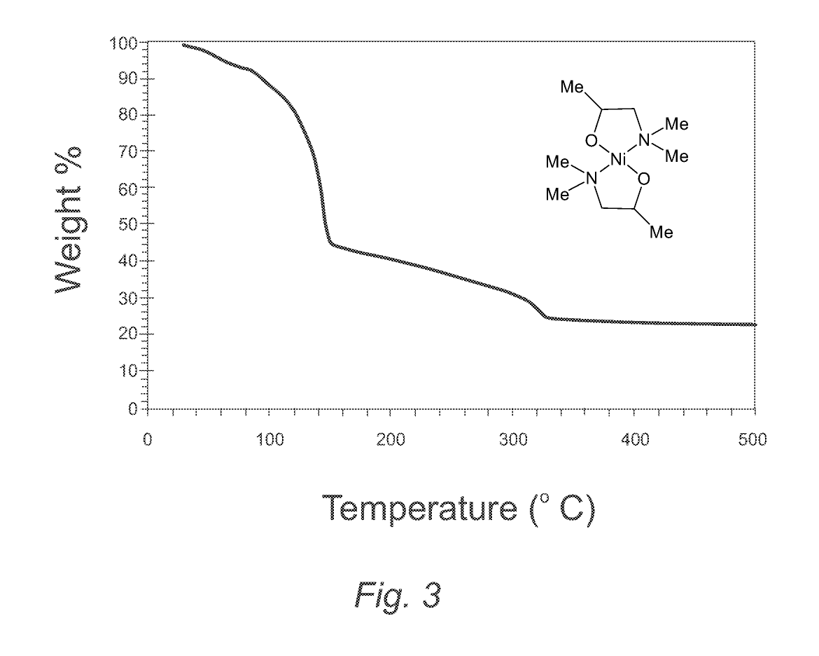

Complex 2 crystallizes as a monomer with two η²-aminoalkoxide ligands bonded to a square planar nickel center. Complex 2 possesses a twofold rotational axis which relates the two halves of the molecule. Complex 2 has two conformations in the solid state. For complex 2, the nickel-oxygen and nickel-nitrogen bond lengths are 1.8398(13) and 1.9397(14) Å, respectively. For the two conformations, the carbon-oxygen bond lengths of the aminoalkoxide cores are 1.4392(10) and 1.4405(10) Å, while the carbon-nitrogen bond lengths are 1.4719(10) and 1.4723(10) Å. The carbon-carbon bond lengths are 1.511(6) and 1.526(9) Å. The oxygen-nickel-oxygen bite angle is 88.14(5)°. FIG. 2 provides the X-ray crystal structure of complex 2 with thermal ellipsoids at 50% probability level. FIG. 3 provides thermogravimetric analysis (TGA) performed to understand the thermal stability and volatility of complex 2. Complex 2 shows a multiple step weight loss occurring between 30 and 330° C. due to its air sensitive nature. The residues upon reaching 500° C. were ≦22.8%.

### Experimental for Cu ALD Film Growth

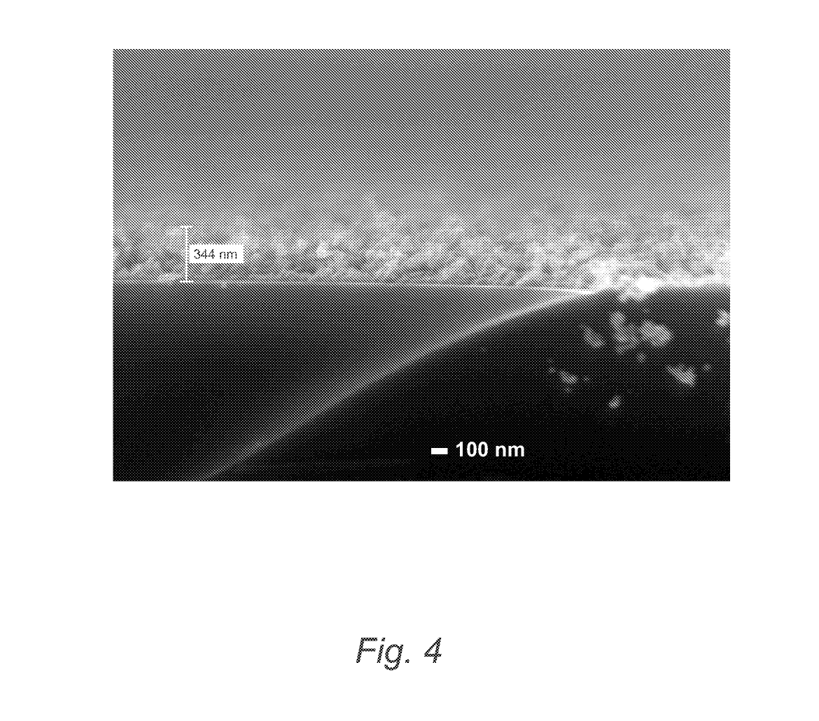

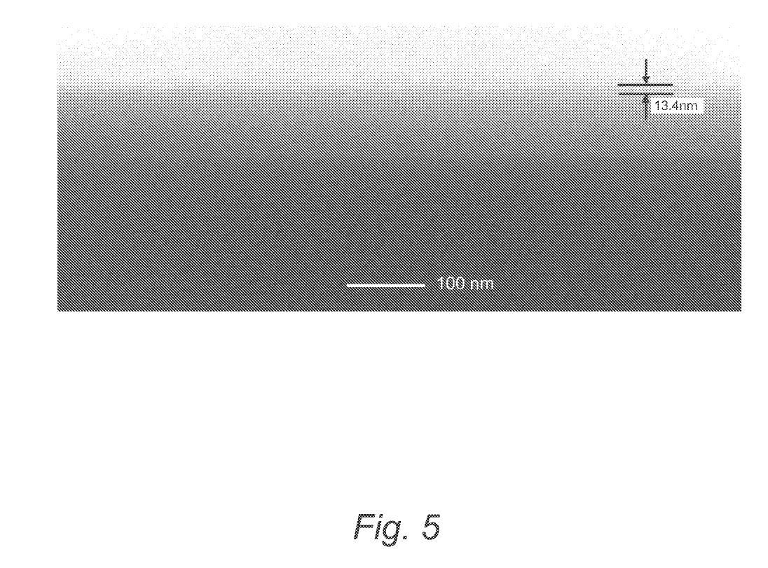

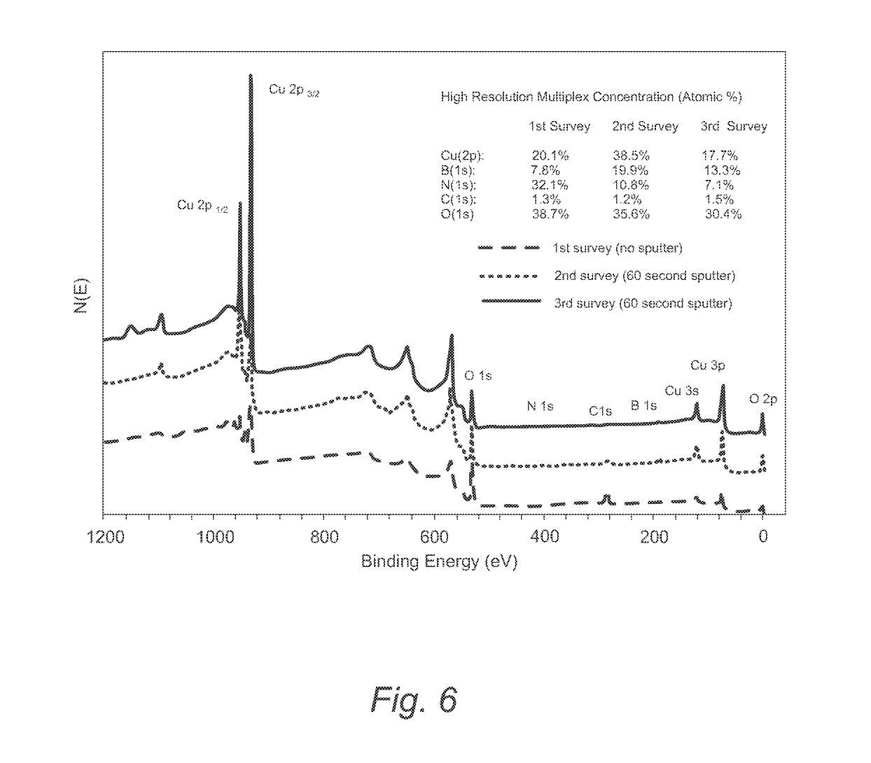

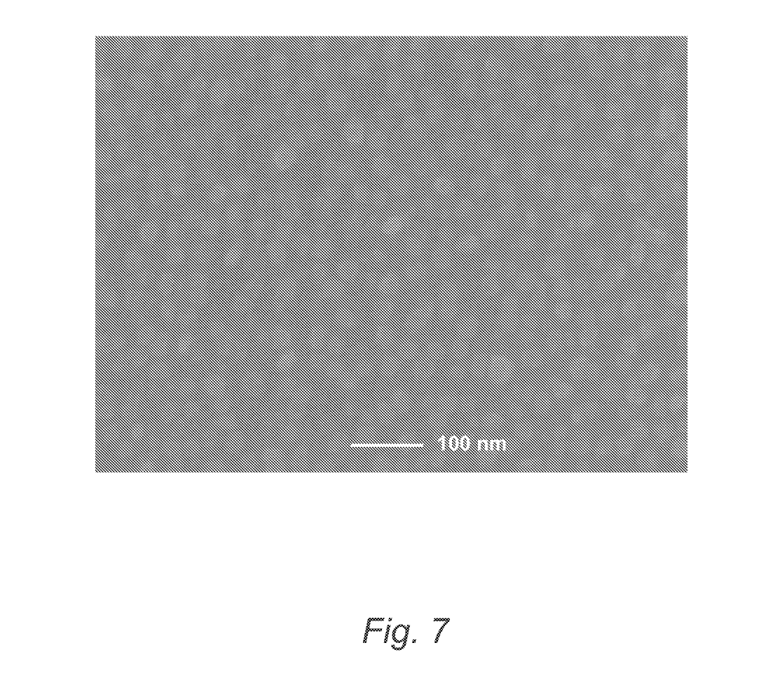

Growth of Cu films by ALD is carried out using Cu(dmap)₂ (dmap=dimethylamino-2-propoxide) and borane N,N-diisopropylethylamine. The temperature of the Cu(dmap)₂ source is maintained at 100° C. The number of deposition cycles, length of Cu(dmap)₂, borane N,N-diisopropylethylamine pulses, and inert gas purge times are kept constant at 1000, 3.0 seconds, 0.3 seconds, and 5.0 seconds, respectively. As shown in the cross-sectional SEM of FIG. 4, a copper film with a thickness of approximately 344 nm is deposited at these conditions. This corresponds to a growth rate of 3.44 Å per cycle. A lower growth rate of 0.13 Å per cycle is observed when the inert gas purge lengths are increased to 10 seconds (FIG. 5). FIG. 6 provides an x-ray photoelectron spectroscopy (XPS) spectrum of a Cu film deposited on SiO₂ at 150° C. using borane N,N-diisopropylethylamine at purge lengths of 5 seconds. FIG. 7 provides a surface SEM micrograph of a Cu film deposited on Ru/SiO₂ at 150° C. using borane N,N-diisopropylethylamine at purge lengths of 10 seconds. A key requirement of ALD growth is that all of the available surface sites react with the gaseous precursor during each precursor pulse. Once this condition is met, a constant growth rate is observed even with excess precursor flow, provided that the precursor does not undergo thermal decomposition. Under optimized deposition conditions (3.0 s Cu(dmap)₂, 5.0 s purge, 0.3 s borane N,N-diisopropylethylamine, 10.0 s purge), a 1000 cycle deposition required about 5.0 hours on our Picosun R-75BE reactors.

### Experimental for Solution Reactions

Solution reactions are executed using 100 mg of the desired precursor dissolved in 20 mL of tetrahydrofuran or toluene. Under inert conditions, the reducing agent of choice is then added slowly until complete addition. After 15 minutes of vigorous stirring, the solution is then allowed to settle to observe for precipitate formation. If no precipitate is present, then the reaction is allowed to stir under refluxing conditions for 18 hours.

TABLE 1
Summary of solution reactions between transition metal alkoxides and various borane
reducing agents.

| Reducing Agent: | Mn(OMe)₂ | Co(OiPr)₂ | Ni(OCHMeCH₂NMe₂)₂ | Cu(OCHMeCH₂NMe₂)₂ |
|---|---|---|---|---|
| H₃B•NEt₃ | No | No | Yes | Yes |
| | | | (product includes metallic Ni) | |
| H₃B•NHMe₂ | No | | Yes | Yes |
| H₃B•SMe₂ | No | No | No | Yes |
| BN(Et)iPr₂ | No | No | No | Yes |
| BH₃•THF | No | No | No | Yes |
| Decaborane | No | No | No | Yes |
| B₁₀H₁₄ | | | | |
| Borane Pyridine | No | No | No | Yes |
| Adduct | | | | |
| 2-picoline borane 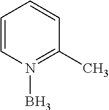 | No | | No | Yes |
| Catechol borane 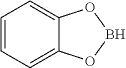 | No | No | No | Yes |
| Borane Morpholine 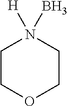 | No | | No | Yes |
| 9-BBN 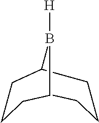 | No | | No | Yes |
| Bis- pinacolatodiboron 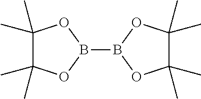 | No | | No | Yes |
| Pinacolborane 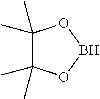 | No | | No | Yes |

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

1.-12. (canceled)

13. A method for forming a metal film on a substrate, the method comprising a deposition cycle including:
a) contacting the substrate with vapor of a compound having formula 1 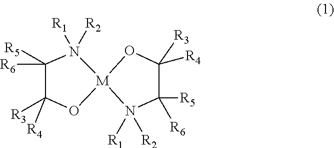
such that at least a portion of the vapor of the compound having formula 1 adsorbs or reacts with a substrate surface to form a modified surface; and
b) contacting the modified surface with a vapor of a borane to react and form at least a portion of the metal film,
wherein:
M is Cu, Ni, Co, and Mn;
R₁R₂, R₃ are each independently C₁-C₆ alkyl; and
R₄-R₆ are each independently hydrogen or C₁-C₆ alkyl.

14. The method of claim 13 wherein the borane is an amine borane.

15. The method of claim 14 wherein the amine borane has formula 2: 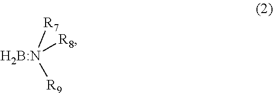
and
R₇-R₉ are each independently hydrogen or C₁-C₆ alkyl.

16. The method of claim 15 wherein R₇, R₈, and R₉ are each independently selected from the group consisting of methyl, isopropyl, n-propyl, n-butyl, sec-butyl, and iso-butyl.

17. The method of claim 15 wherein R₇ and R₈, are joined to form a 5 or 6 membered ring.

18. The method of claim 17 wherein the amine borane has formula (3):

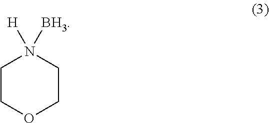

19. The method of claim 15 wherein the amine borane has formula (4): 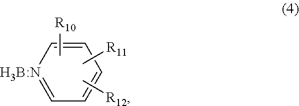
and
R₁₀-R₁₂ are each independently C₁-C₆ alkyl.

20. The method of claim 14 wherein R₁, R₂, R₃ are each independently methyl and R₄-R₆ are each independently hydrogen.

21. The method of claim 14 wherein the compound having formula 1 is contacted with the amine borane at a temperature from about 150 to 400° C.

22. The method of claim 14 further comprising at least one additional deposition cycle.

23. The method of claim 14 further comprising 1 to 1000 additional deposition cycles.

24. The method of claim 13 wherein M is Ni, Co, or Mn.

25. The method of claim 13 wherein M is Co.

26. The method of claim 13 wherein M is Ni
